(19) United States
(12) Patent Application Publication
(10) Pub. No.: US 2011/0284911 A1
(43) Pub. Date: Nov. 24, 2011

(54) LIGHT EMITTING DIODE CHIP AND MANUFACTURING METHOD THEREOF

(75) Inventor: YEN-CHIH CHIANG, Taichung City (TW)

(73) Assignee: Lextar Electronics Corp., Hsinchu (TW)

(21) Appl. No.: 13/048,211

(22) Filed: Mar. 15, 2011

(30) Foreign Application Priority Data
May 21, 2010 (TW) 99116310

(51) Int. Cl. H01L 33/02; H01L 33/62

(52) U.S. Cl. 257/99; 438/33; 438/28; 257/E33.012; 257/E33.056; 257/E33.066

(57) ABSTRACT

A light emitting diode (LED) chip includes a substrate, a light emitting semiconductor device, a first electrode, and a second electrode. The light emitting semiconductor device has a recess and includes a first portion and a second portion. The first portion is disposed on the substrate and located between the second portion and the substrate. The recess penetrates the second portion and exposes an exposed region of the first portion. The transverse sectional area of the first portion and the transverse sectional area of the second portion increase along a direction away from the substrate. The first electrode is disposed on the exposed region of the first portion and electrically connected to the first portion. The second electrode is disposed on and electrically connected to the second portion.

### CROSS-REFERENCE TO RELATED APPLICATION

This application claims the priority benefit of Taiwan application serial no. 99116310, filed on May 21, 2010. The entirety of the above-mentioned patent application is hereby incorporated by reference herein and made a part of this specification.

### BACKGROUND OF THE INVENTION

1. Field of the Invention

The invention relates to a light emitting diode (LED) chip, and more particularly to an LED chip having favorable lateral light extraction efficiency.

2. Description of Related Art

Due to advantages of long lifetime, small volume, great resistance to vibration, low heat emission, and low power consumption, LEDs have been extensively applied to various home appliances and instruments as indicators or light sources. In recent years, the LEDs have been developed toward multiple colors and high brightness; therefore, the application scope of the LEDs has been expanded to large outdoor display boards, traffic signal lights, and the like. In the future, the LED may even become the main illumination light source with both power-saving and environment-protecting functions.

FIG. 1 is a cross-sectional view illustrating a conventional LED chip. As shown in FIG. 1, a conventional LED chip 100 includes an insulating substrate 110, a first-type doped semiconductor layer 120, a light emitting layer 130, a second-type doped semiconductor layer 140, a first electrode 150, and a second electrode 160. The first-type doped semiconductor layer 120, the light emitting layer 130, and the second-type doped semiconductor layer 140 are sequentially stacked on the insulating substrate 110. The LED chip 100 has a recess 102 penetrating the second-type doped semiconductor layer 140 and the light emitting layer 130. Light emitted from the light emitting layer 130 can be transmitted out of a top surface 104 of the LED chip 100 or a sidewall 106 connecting the top surface 104. Nonetheless, the light emitted from the light emitting layer 130 is apt to be transmitted into the sidewall 106 at a relatively wide incident angle, such that total reflection is likely to occur at the sidewall 106, and that the light is easily absorbed by materials during reflection within the LED chip 100. Thereby, the light extraction efficiency at the sidewall 106 of the LED chip 100 is rather low.

### SUMMARY OF THE INVENTION

The invention is directed to an LED chip having favorable lateral light extraction efficiency.

In the invention, an LED chip including a substrate, a light emitting semiconductor device, a first electrode, and a second electrode is provided. The light emitting semiconductor device has a recess and includes a first portion and a second portion. The first portion is disposed on the substrate and located between the second portion and the substrate. The recess penetrates the second portion and exposes an exposed region of the first portion. A transverse sectional area of the first portion and a transverse sectional area of the second portion increase along a direction away from the substrate. The first electrode is disposed on the exposed region of the first portion and electrically connected to the first portion. The second electrode is disposed on the second portion and electrically connected to the second portion.

According to an embodiment of the invention, the light emitting semiconductor device includes a first-type doped semiconductor layer, a light emitting layer disposed on the first-type doped semiconductor layer, and a second-type doped semiconductor layer disposed on the light emitting layer.

According to an embodiment of the invention, the first-type doped semiconductor layer is located in the first portion, and the light emitting layer and the second-type doped semiconductor layer are located in the second portion.

According to an embodiment of the invention, a portion of the first-type doped semiconductor layer is located in the first portion, and the other portion of the first-type doped semiconductor layer, the light emitting layer, and the second-type doped semiconductor layer are located in the second portion.

According to an embodiment of the invention, the light emitting semiconductor device has an under-cut sidewall formed by a first sidewall of the first portion and a second sidewall of the second portion.

According to an embodiment of the invention, an area of the exposed region is A, the maximum transverse sectional area of the second portion is B, and A/(A+B)≦0.15.

According to an embodiment of the invention, A/(A+B)≦0.1.

According to an embodiment of the invention, the recess is located at an edge of the light emitting semiconductor device.

In the invention, an LED chip including a conductive substrate, a light emitting semiconductor device, and an electrode is provided. The light emitting semiconductor device is disposed on the conductive substrate and includes a first-type doped semiconductor layer, a light emitting layer disposed on the first-type doped semiconductor layer, and a second-type doped semiconductor layer disposed on the light emitting layer. The first-type doped semiconductor layer has a first surface facing the conductive substrate, and the second-type doped semiconductor layer has a second surface facing against the conductive substrate. A transverse sectional area of the light emitting semiconductor device decreases from the first surface to the second surface. The electrode is disposed on the second surface and electrically connected to the second-type doped semiconductor layer.

According to an embodiment of the invention, the light emitting semiconductor device has a sidewall connecting the first surface and the second surface. The LED chip further includes a passivation layer covering the sidewall of the light emitting semiconductor device.

According to an embodiment of the invention, the passivation layer further covers a portion of the first surface.

According to an embodiment of the invention, the LED chip further includes a conductive bonding layer connected between the conductive substrate and the light emitting semiconductor device.

In the invention, a manufacturing method of an LED chip is provided. According to the manufacturing method, a light emitting semiconductor material layer is formed on a substrate. A plurality of recesses are formed on the light emitting semiconductor material layer. A depth of each of the recesses is less than a thickness of the light emitting semiconductor material layer. A mask layer is formed on the light emitting semiconductor material layer. A plurality of trenches penetrating the mask layer and the light emitting semiconductor material layer are formed, so as to divide the light emitting semiconductor material layer into a plurality of light emitting semiconductor devices separated from one another. Each of the light emitting semiconductor devices has one of the recesses. A portion of the light emitting semiconductor devices exposed by the trenches is etched with use of the mask layer as a mask, such that a width of each of the trenches increases along a direction toward the substrate. The mask layer is removed. A first electrode is formed in the recess of each of the light emitting semiconductor devices, and a second electrode is formed on a surface of each of the light emitting semiconductor devices. Here, the surface is located outside the recess and faces a direction away from the substrate.

According to an embodiment of the invention, the manufacturing method of the LED chip further includes cutting the substrate along the trenches to form the LED chips separated from one another.

According to an embodiment of the invention, a method of forming the recesses includes dry etching or wet etching.

According to an embodiment of the invention, a method of forming the trenches includes mechanical cutting or laser cutting.

According to an embodiment of the invention, a method of etching the portion of the light emitting semiconductor devices exposed by the trenches includes dry etching or wet etching.

According to an embodiment of the invention, each of the light emitting semiconductor devices has a first portion and a second portion after the portion of the light emitting semiconductor devices exposed by the trenches is etched with use of the mask layer. The first portion is located between the second portion and the substrate. The recess of each of the light emitting semiconductor devices penetrates the second portion and exposes an exposed region of the first portion. A transverse sectional area of the first portion and a transverse sectional area of the second portion increase along a direction away from the substrate.

According to an embodiment of the invention, the light emitting semiconductor device includes a first-type doped semiconductor layer, a light emitting layer disposed on the first-type doped semiconductor layer, and a second-type doped semiconductor layer disposed on the light emitting layer.

In the invention, a manufacturing method of an LED chip is provided. According to the manufacturing method, a light emitting semiconductor material layer is formed on a substrate. The light emitting semiconductor material layer includes a second-type doped semiconductor layer, a light emitting layer disposed on the second-type doped semiconductor layer, and a first-type doped semiconductor layer disposed on the light emitting layer. A mask layer is formed on the light emitting semiconductor material layer. A plurality of trenches penetrating the mask layer and the light emitting semiconductor material layer are formed, so as to divide the light emitting semiconductor material layer into a plurality of light emitting semiconductor devices separated from one another. A portion of the light emitting semiconductor devices exposed by the trenches is etched with use of the mask layer as a mask, such that a width of each of the trenches increases along a direction toward the substrate. The mask layer is removed. The light emitting semiconductor devices are connected to a conductive substrate. Here, the light emitting semiconductor devices are located between the conductive substrate and the substrate. The substrate is removed. An electrode is formed on a first surface of each of the light emitting semiconductor devices, wherein the first surface faces against the conductive substrate.

According to an embodiment of the invention, the manufacturing method of the LED chip further includes cutting the conductive substrate along the trenches to form the LED chips separated from one another.

According to an embodiment of the invention, the manufacturing method of the LED chip further includes forming a passivation layer on a sidewall of each of the light emitting semiconductor devices after the portion of the light emitting semiconductor devices exposed by the trenches is etched with use of the mask layer.

According to an embodiment of the invention, the manufacturing method of the LED chip further includes forming a conductive bonding layer on the conductive substrate or on a second surface of each of the light emitting semiconductor devices before the light emitting semiconductor devices are connected to the conductive substrate, such that each of the light emitting semiconductor devices is connected to the conductive substrate through the conductive bonding layer. Here, the second surface faces against the substrate.

According to an embodiment of the invention, a method of forming the trenches includes mechanical cutting or laser cutting.

According to an embodiment of the invention, a method of etching the portion of the light emitting semiconductor devices exposed by the trenches includes dry etching or wet etching.

According to an embodiment of the invention, each of the light emitting semiconductor devices has a first surface and a second surface opposite to the first surface after the portion of the light emitting semiconductor devices exposed by the trenches is etched. Each of the first surfaces connects the substrate. A transverse sectional area of each of the light emitting semiconductor devices increases from the first surface to the second surface.

Based on the above, the transverse sectional area of the light emitting semiconductor device in the LED chip differs from a distance from the light emitting semiconductor device to the substrate according to this invention. Hence, the sidewall of the LED chip can be an inclined surface. As such, the light emitted from the light emitting layer is prone to be transmitted into the sidewall at a relatively small incident angle and emitted out of the sidewall. Thereby, the light extraction efficiency at the sidewall of the LED chip can be improved, and luminance of the LED chip can be enhanced as well.

In order to make the aforementioned and other features and advantages of the invention more comprehensible, embodiments accompanying figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 is a cross-sectional view illustrating a conventional LED chip.

FIG. 2A to FIG. 2F are cross-sectional views illustrating a manufacturing process of an LED chip according to an embodiment of the invention.

FIG. 3A to FIG. 3F are top views of FIG. 2A to FIG. 2F, and FIG. 2A to FIG. 2F are cross-sectional views along a line segment I-I′ depicted in FIG. 3A to FIG. 3F.

FIG. 4 is a cross-sectional view along a line segment II-II′ depicted in FIG. 3F.

FIG. 5A to FIG. 5G are cross-sectional views illustrating a manufacturing process of an LED chip according to an embodiment of the invention.

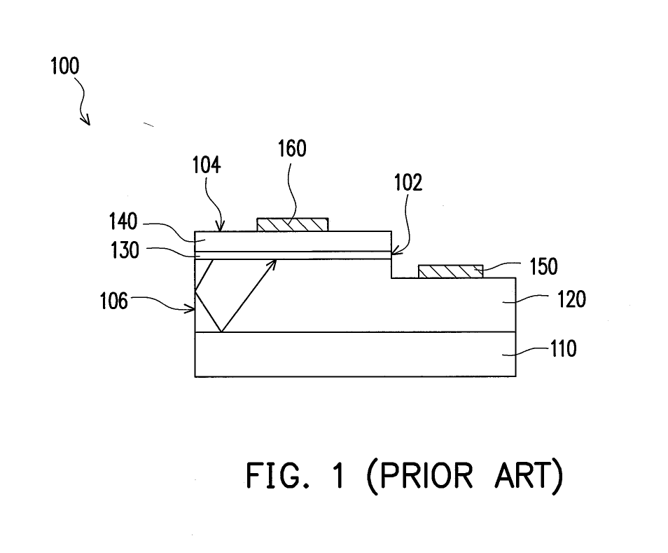

### DESCRIPTION OF EMBODIMENTS

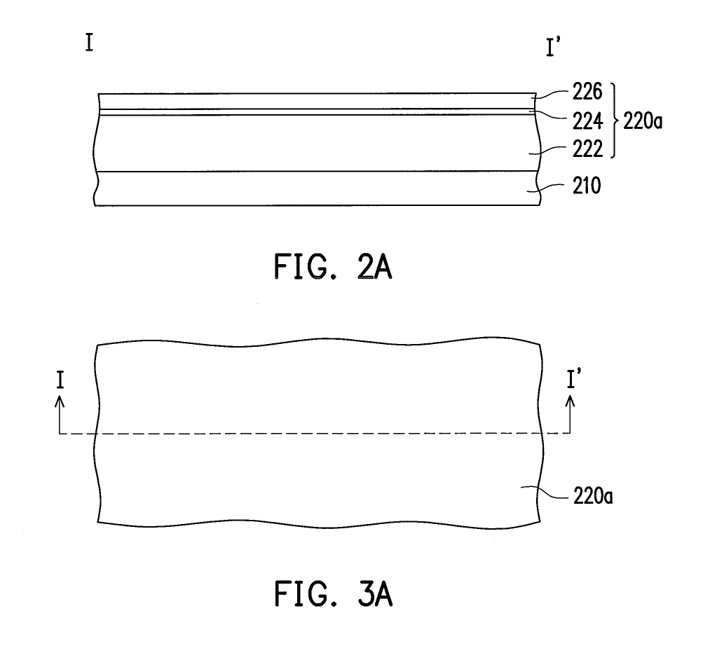

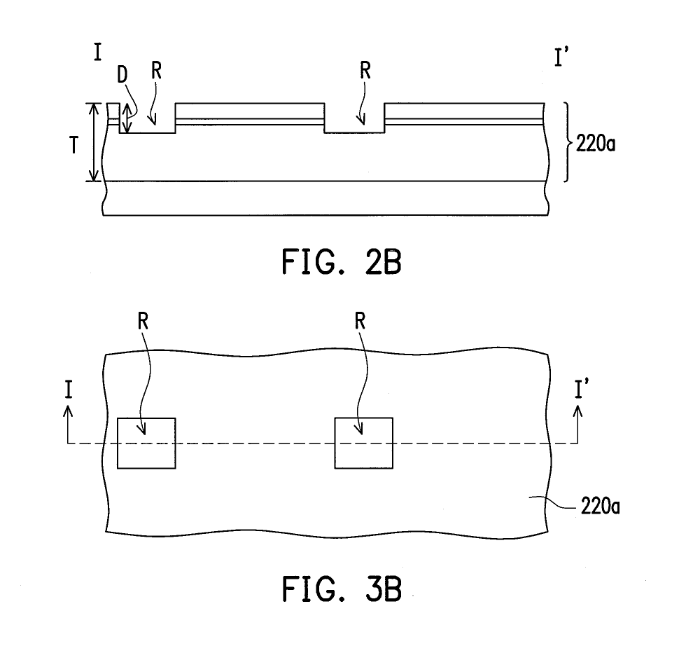

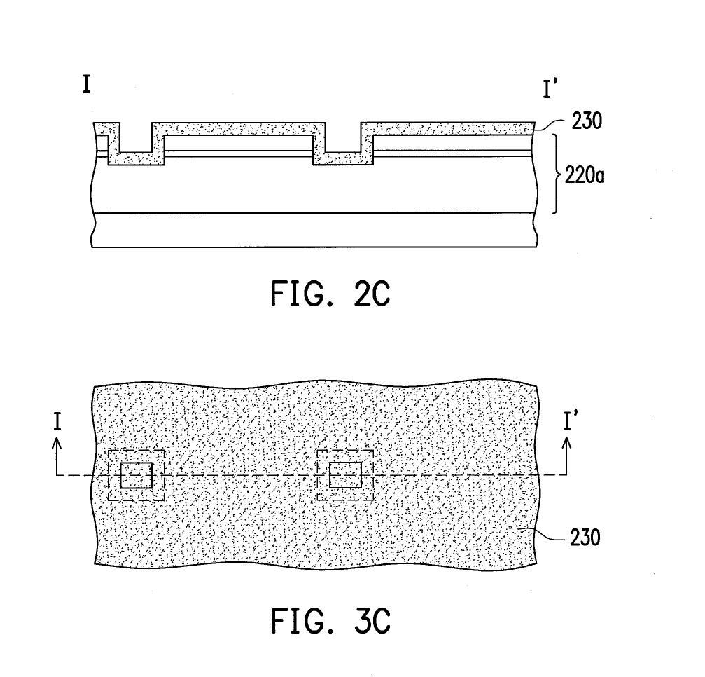

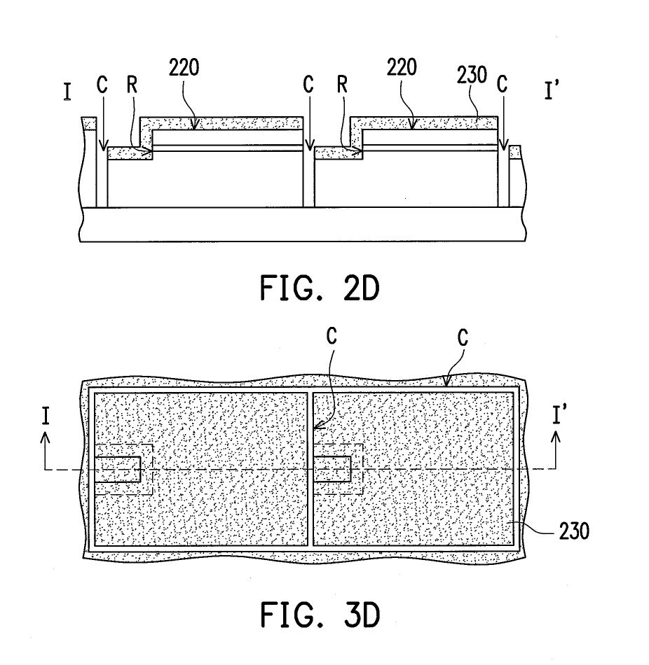

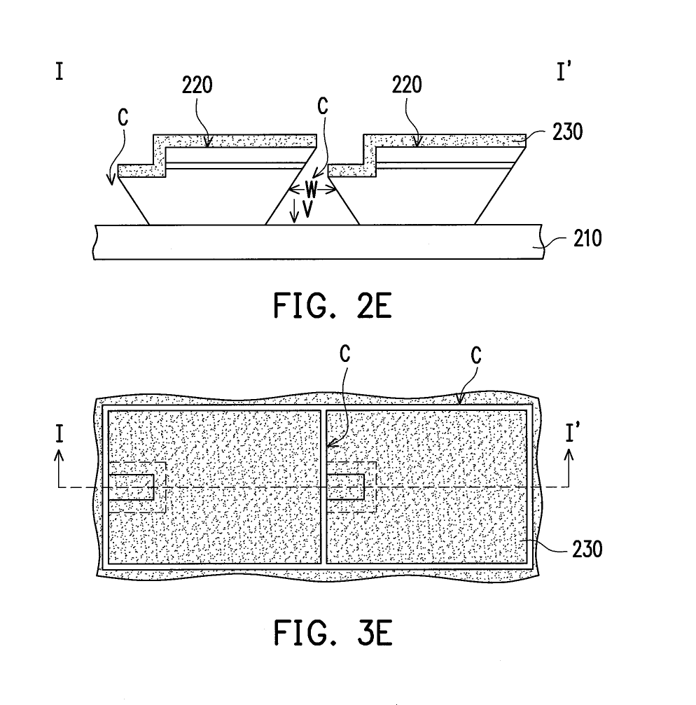

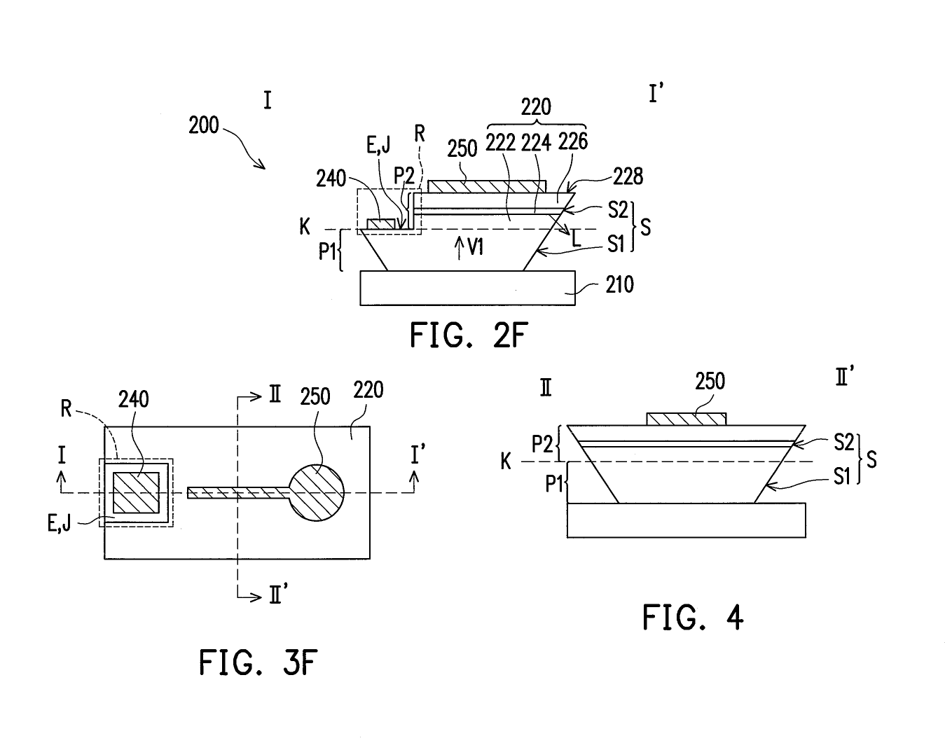

FIG. 2A to FIG. 2F are cross-sectional views illustrating a manufacturing process of an LED chip according to an embodiment of the invention. FIG. 3A to FIG. 3F are top views of FIG. 2A to FIG. 2F, and FIG. 2A to FIG. 2F are cross-sectional views along a line segment I-I′ depicted in FIG. 3A to FIG. 3F. FIG. 4 is a cross-sectional view along a line segment II-II′ depicted in FIG. 3F.

As indicated in FIG. 2A and FIG. 3A, a light emitting semiconductor material layer 220a is formed on a substrate 210. The light emitting semiconductor material layer 220a includes a first-type doped semiconductor layer 222, a light emitting layer 224 disposed on the first-type doped semiconductor layer 222, and a second-type doped semiconductor layer 226 disposed on the light emitting layer 224. The light emitting layer 224 is located between the first-type doped semiconductor layer 222 and the second-type doped semiconductor layer 226, and the first-type doped semiconductor layer 222 is connected to the substrate 210.

With reference to FIG. 2B and FIG. 3B, a plurality of recesses R are formed on the light emitting semiconductor material layer 220a. A method of forming the recesses R, for example, is dry etching, wet etching, or any other method suitable for etching the semiconductor material. A depth D of each of the recesses R is less than a thickness T of the light emitting semiconductor layer 220a. Namely, the recesses R do not penetrate the light emitting semiconductor material layer 220a.

With reference to FIG. 2C and FIG. 3C, a mask layer 230 is formed on the light emitting semiconductor material layer 220a. A material of the mask layer 230, for example, is silicon dioxide or any other anti-etching material.

As shown in FIG. 2D and FIG. 3D, a plurality of trenches C penetrating the mask layer 230 and the light emitting semiconductor material layer 220a are formed by applying a mechanical cutting method or a laser cutting method, for instance, so as to divide the light emitting semiconductor material layer 220a into a plurality of light emitting semiconductor devices 220 separated from one another. Each of the light emitting semiconductor devices 220 has one of the recesses R.

With reference to FIG. 2E and FIG. 3E, a portion of the light emitting semiconductor devices 220 exposed by the trenches C is etched with use of the mask layer 230 as a mask, such that a width W of each of the trenches C increases along a direction V toward the substrate 210. According to this embodiment, a method of etching the portion of the light emitting semiconductor devices 220 exposed by the trenches C includes dry etching, wet etching, or any other appropriate isotropic etching.

To be more specific, in this embodiment, the isotropic etching process is performed on the light emitting semiconductor devices 220, and the mask layer 230 is an anti-etching material layer. Hence, during the etching process, an under-cut phenomenon occurs at the portion of the light emitting semiconductor devices 220 exposed by the trenches C (i.e. the portion of the light emitting semiconductor devices 220 exposed by the mask layer 230), such that the width W of each of the trenches C increases along the direction V toward the substrate 210.

As indicated in FIG. 2F, FIG. 3F, and FIG. 4, the mask layer 230 is removed, a first electrode 240 is formed in the recess R of each of the light emitting semiconductor devices 220, and a second electrode 250 is formed on a surface 228 of each of the light emitting semiconductor devices 220. Here, the surface 228 is located outside the recess R and faces a direction V1 away from the substrate 210.

According to this embodiment, the substrate 210 can be selectively cut along the trenches C to form a plurality of the LED chips 200 separated from one another.

The structure of the LED chip 200 is elaborated hereinafter.

As shown in FIG. 2F, FIG. 3F, and FIG. 4, an LED chip 200 of this embodiment includes a substrate 210, a light emitting semiconductor device 220, a first electrode 240, and a second electrode 250. The light emitting semiconductor device 220 includes a first-type doped semiconductor layer 222, a light emitting layer 224 disposed on the first-type doped semiconductor layer 222, and a second-type doped semiconductor layer 226 disposed on the light emitting layer 224.

The light emitting semiconductor device 220 has a recess R which is, for example, located at an edge of the light emitting semiconductor device 220. The light emitting semiconductor device 220 includes a first portion P1 and a second portion P2. The first portion P1 is disposed on the substrate 210 and located between the second portion P2 and the substrate 210 The recess R penetrates the second portion P2 and exposes an exposed region E of the first portion P1. In this embodiment, the light emitting semiconductor device 220 is divided by a plane K into the first portion P1 and the second portion P2. The plane K is where a bottom surface J of the recess R is located.

A transverse sectional area of the first portion P1 and a transverse sectional area of the second portion P2 increase along a direction V1 away from the substrate 210. In particular, according to this embodiment, the light emitting semiconductor device 220 has an under-cut sidewall S formed by a first sidewall S1 of the first portion P1 and a second sidewall S2 of the second portion P2.

Note that the under-cut sidewall S is an inclined sidewall, and therefore light L emitted from the light emitting layer 224 is prone to be transmitted into the under-cut sidewall S at a relatively small incident angle and emitted out of the under-cut sidewall S. Thereby, the light extraction efficiency at the sidewall of the LED chip 200 can be improved, and luminance of the LED chip 200 can be enhanced as well.

In this embodiment, an area of the exposed region E is A, the maximum transverse sectional area of the second portion P2 is B, and A/(A+B)≦0.15. e.g. A/(A+B)≦0.1. Note that the exposed region E of this embodiment occupies a relatively small area, and the light emitting layer 224 and the second-type doped semiconductor layer 226 occupy a relatively large area. Accordingly, the probability of combining electrons and holes in the LED chip 200 can be increased, and luminance of the LED chip 200 can be further enhanced.

According to this embodiment, a portion of the first-type doped semiconductor layer 222 is located in the first portion P1, and the other portion of the first-type doped semiconductor layer 222, the light emitting layer 224, and the second-type doped semiconductor layer 226 are located in the second portion P2. Namely, in this embodiment, the recess R not only penetrates the light emitting layer 224 and the second-type doped semiconductor layer 226 but extends into the first-type doped semiconductor layer 222.

In other embodiments, the first-type doped semiconductor layer 222 is located in the first portion P1, and the light emitting layer 224 and the second-type doped semiconductor layer 226 are located in the second portion P2. That is to say, the recess R merely penetrates the light emitting layer 224 and the second-type doped semiconductor layer 226 without extending into the first-type doped semiconductor layer 222.

The first electrode 240 is disposed on the exposed region E of the first portion P1 and electrically connected to the first-type doped semiconductor layer 222. The second electrode 250 is disposed on the second portion P2 and electrically connected to the second-type doped semiconductor layer 226.

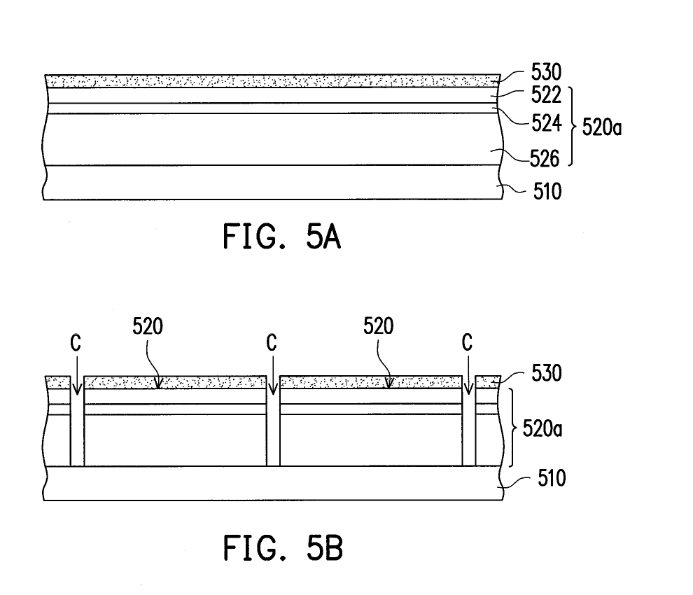

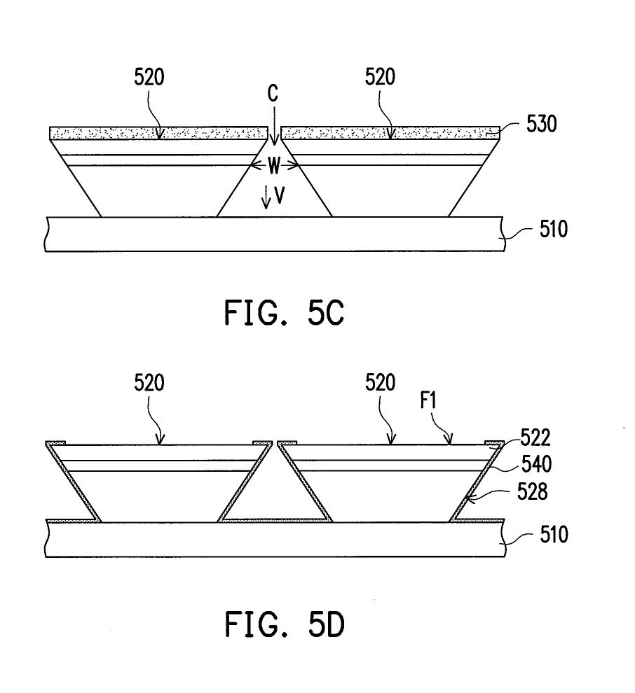

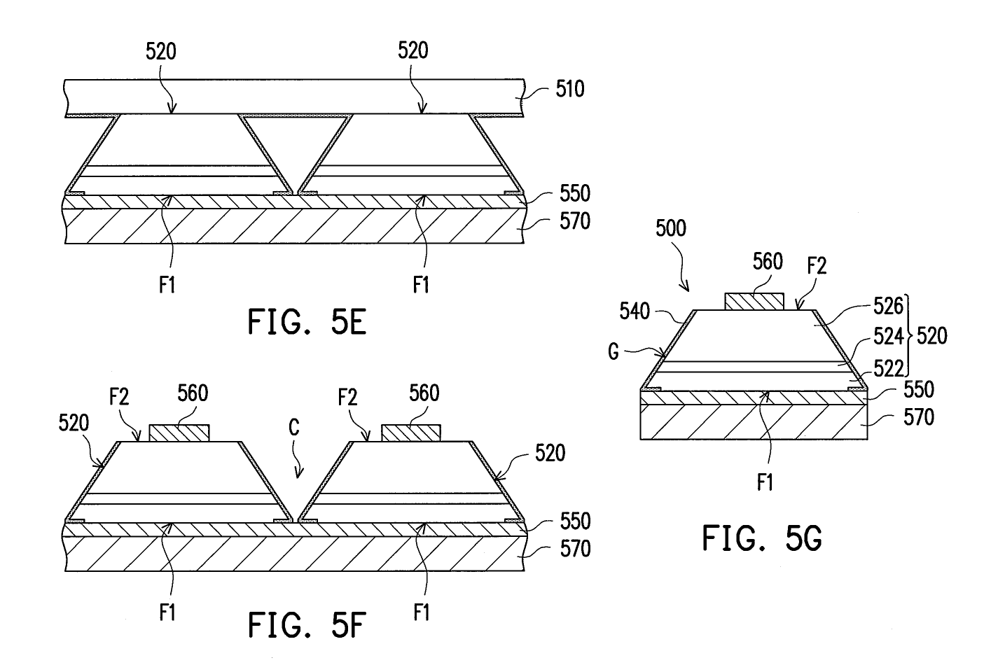

FIG. 5A to FIG. 5G are cross-sectional views illustrating a manufacturing process of an LED chip according to an embodiment of the invention.

With reference to FIG. 5A, a light emitting semiconductor material layer 520a is formed on a substrate 510. The light emitting semiconductor material layer 520a includes a second-type doped semiconductor layer 526, a light emitting layer 524 disposed on the second-type doped semiconductor layer 526, and a first-type doped semiconductor layer 522 disposed on the light emitting layer 524. A mask layer 530 is formed on the light emitting semiconductor material layer 520a.

As indicated in FIG. 5B, the mask layer 530 and the light emitting semiconductor layer 520a are cut to form a plurality of trenches C penetrating the mask layer 530 and the light emitting semiconductor material layer 520a. The trenches C divide the light emitting semiconductor material layer 520a into a plurality of light emitting semiconductor devices 520 separated from one another. A method of cutting the mask layer 530 and the light emitting semiconductor material layer 520a is mechanical cutting or laser cutting, for example.

With reference to FIG. 5C, a portion of the light emitting semiconductor devices 520 exposed by the trenches C is etched with use of the mask layer 530 as a mask, such that a width W of each of the trenches C increases along a direction V toward the substrate 510. According to this embodiment, a method of etching the portion of the light emitting semiconductor devices 520 exposed by the trenches C is, for example, dry etching, wet etching, or any other appropriate isotropic etching.

In FIG. 5D, the mask layer 530 is removed. A passivation layer 540 can be selectively formed on a sidewall 528 of each of the light emitting semiconductor devices 520. Particularly, in this embodiment, the passivation layer 540 not only can be formed on the sidewall 528 but also can be formed on the substrate 510 between a portion of the first-type doped semiconductor layer 522 and the light emitting semiconductor devices 520.

In FIG. 5E, the light emitting semiconductor devices 520 are connected to a conductive substrate 570. Here, the light emitting semiconductor devices 520 are located between the conductive substrate 570 and the substrate 510.

To be more specific, a conductive bonding layer 550 can be selectively formed on the conductive substrate 570 or on a first surface F1 of each of the light emitting semiconductor devices 520 before the light emitting semiconductor devices 520 are connected to the conductive substrate 570, such that each of the light emitting semiconductor devices 520 can be connected to the conductive substrate 570 through the conductive bonding layer 550. Here, the first surface F1 faces against the substrate 510.

With reference to FIG. 5F, the substrate 510 is removed, and an electrode 560 is formed on a second surface F2 of each of the light emitting semiconductor devices 520. The second surface F2 faces against the conductive substrate 570. Here, a method of removing the substrate 510 is, for example, laser lift-off.

As shown in FIG. 5G, in this embodiment, the conductive substrate 570 can be selectively cut along the trenches C to form a plurality of the LED chips 500 separated from one another. Note that only one of the LED chips 500 is depicted in FIG. 5G.

The structure of the LED chip 500 is elaborated hereinafter.

As shown in FIG. 5G, an LED chip 500 of this embodiment includes a conductive substrate 570, a light emitting semiconductor device 520, and an electrode 560. The light emitting semiconductor device 520 includes a first-type doped semiconductor layer 522, a light emitting layer 524 disposed on the first-type doped semiconductor layer 522, and a second-type doped semiconductor layer 526 disposed on the light emitting layer 524.

The light emitting semiconductor device 520 is disposed on the conductive substrate 570. Here, a conductive bonding layer 550 can be selectively disposed between the light emitting semiconductor device 520 and the conductive substrate 570, so as to connect the light emitting semiconductor device 520 and the conductive substrate 570.

The first-type doped semiconductor layer 522 has a first surface F1 facing the conductive substrate 570, and the second-type doped semiconductor layer 526 has a second surface F2 facing against the conductive substrate 570. A transverse sectional area of the light emitting semiconductor device 520 decreases from the first surface F1 to the second surface F2. Namely, the light emitting semiconductor device 520 is a pyramid with a tangent plane. The electrode 560 is disposed on the second surface F2 and electrically connected to the second-type doped semiconductor layer 526.

In this embodiment, the light emitting semiconductor device 520 has a sidewall G connecting the first surface F1 and the second surface F2. A passivation layer 540 covers the sidewall G of the light emitting semiconductor device 520. Besides, the passivation layer 540 of this embodiment can further cover a portion of the first surface F1.

In light of the foregoing, the transverse sectional area of the light emitting semiconductor device in the LED chip differs from a distance from the light emitting semiconductor device to the substrate according to this invention. Hence, the sidewall of the LED chip can be an inclined surface. As such, the light emitted from the light emitting layer is prone to be transmitted into the sidewall at a relatively small incident angle and emitted out of the sidewall. Thereby, the light extraction efficiency at the sidewall of the LED chip can be improved, and luminance of the LED chip can be enhanced as well.

Moreover, the first portion exposed by the groove of the invention occupies a relatively small area, and the light emitting layer and the second-type doped semiconductor layer occupy a relatively large area. Accordingly, the probability of combining electrons and holes in the LED chip can be increased, and luminance of the LED chip can be further enhanced.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A light emitting diode chip comprising:
a substrate;
a light emitting semiconductor device having a recess and comprising:
a first portion disposed on the substrate;
a second portion, the first portion being located between the second portion and the substrate, the recess penetrating the second portion and exposing an exposed region of the first portion, wherein a transverse sectional area of the first portion and a transverse sectional area of the second portion increase along a direction away from the substrate;
a first electrode disposed on the exposed region of the first portion and electrically connected to the first portion; and
a second electrode disposed on and electrically connected to the second portion.

2. The light emitting diode chip as claimed in claim 1, wherein the light emitting semiconductor device comprises a first-type doped semiconductor layer, a light emitting layer disposed on the first-type doped semiconductor layer, and a second-type doped semiconductor layer disposed on the light emitting layer.

3. The light emitting diode chip as claimed in claim 2, wherein the first-type doped semiconductor layer is located in the first portion, and the light emitting layer and the second-type doped semiconductor layer are located in the second portion.

4. The light emitting diode chip as claimed in claim 2, wherein a portion of the first-type doped semiconductor layer is located in the first portion, and the other portion of the first-type doped semiconductor layer, the light emitting layer, and the second-type doped semiconductor layer are located in the second portion.

5. The light emitting diode chip as claimed in claim 1, wherein the light emitting semiconductor device has an under-cut sidewall formed by a first sidewall of the first portion and a second sidewall of the second portion.

6. The light emitting diode chip as claimed in claim 1, wherein an area of the exposed region is A, a maximum transverse sectional area of the second portion is B, and A/(A+B)≦0.15.

7. The light emitting diode chip as claimed in claim 6, wherein A/(A+B)≦0.1.

8. The light emitting diode chip as claimed in claim 1, wherein the recess is located at an edge of the light emitting semiconductor device.

9. A light emitting diode chip comprising:
a conductive substrate;
a light emitting semiconductor device disposed on the conductive substrate and comprising a first-type doped semiconductor layer, a light emitting layer disposed on the first-type doped semiconductor layer, and a second-type doped semiconductor layer disposed on the light emitting layer, the first-type doped semiconductor layer having a first surface facing the conductive substrate, the second-type doped semiconductor layer having a second surface facing against the conductive substrate, a transverse sectional area of the light emitting semiconductor device decreasing from the first surface to the second surface; and
an electrode disposed on the second surface and electrically connected to the second-type doped semiconductor layer.

10. The light emitting diode chip as claimed in claim 9, wherein the light emitting semiconductor device has a sidewall connecting the first surface and the second surface, and the light emitting diode chip further comprises:
a passivation layer covering the sidewall.

11. The light emitting diode chip as claimed in claim 10, wherein the passivation layer further covers a portion of the first surface.

12. The light emitting diode chip as claimed in claim 9, further comprising:
a conductive bonding layer connected between the conductive substrate and the light emitting semiconductor device.

13. A manufacturing method of a light emitting diode chip, comprising:
forming a light emitting semiconductor material layer on a substrate;
forming a plurality of recesses on the light emitting semiconductor material layer, wherein a depth of each of the recesses is substantially less than a thickness of the light emitting semiconductor material layer;
forming a mask layer on the light emitting semiconductor material layer;
forming a plurality of trenches penetrating the mask layer and the light emitting semiconductor material layer, so as to divide the light emitting semiconductor material layer into a plurality of light emitting semiconductor devices separated from one another, each of the light emitting semiconductor devices having one of the recesses respectively;
etching a portion of the light emitting semiconductor devices exposed by the trenches with use of the mask layer as a mask, such that a width of each of the trenches increases along a direction toward the substrate;
removing the mask layer; and
forming a first electrode in the recess of each of the light emitting semiconductor devices and forming a second electrode on a surface of each of the light emitting semiconductor devices, the surface being located outside the recess and facing a direction away from the substrate.

14. The manufacturing method as claimed in claim 13, further comprising:
cutting the substrate along the trenches to form a plurality of the light emitting diode chips separated from one another.

15. The manufacturing method as claimed in claim 13, wherein a method of forming the recesses comprises dry etching or wet etching.

16. The manufacturing method as claimed in claim 13, wherein a method of forming the trenches comprises mechanical cutting or laser cutting.

17. The manufacturing method as claimed in claim 13, wherein a method of etching the portion of the light emitting semiconductor devices exposed by the trenches comprises dry etching or wet etching.

18. The manufacturing method as claimed in claim 13, each of the light emitting semiconductor devices having a first portion and a second portion after the portion of the light emitting semiconductor devices exposed by the trenches is etched with use of the mask layer, the first portion being located between the second portion and the substrate, the recess of each of the light emitting semiconductor devices penetrating the second portion and exposing an exposed region of the first portion, wherein a transverse sectional area of the first portion and a transverse sectional area of the second portion increase along a direction away from the substrate.

19. The manufacturing method as claimed in claim 13, wherein each of the light emitting semiconductor devices comprises a first-type doped semiconductor layer, a light emitting layer disposed on the first-type doped semiconductor layer, and a second-type doped semiconductor layer disposed on the light emitting layer.

20. The manufacturing method as claimed in claim 13, wherein a material of the mask layer comprises silicon dioxide.

21. A manufacturing method of a light emitting diode chip, comprising:
forming a light emitting semiconductor material layer on a substrate, the light emitting semiconductor material layer comprising a second-type doped semiconductor layer, a light emitting layer disposed on the second-type doped semiconductor layer, and a first-type doped semiconductor layer disposed on the light emitting layer;
forming a mask layer on the light emitting semiconductor material layer;
forming a plurality of trenches penetrating the mask layer and the light emitting semiconductor material layer, so as to divide the light emitting semiconductor material layer into a plurality of light emitting semiconductor devices separated from one another;
etching a portion of the light emitting semiconductor devices exposed by the trenches with use of the mask layer as a mask, such that a width of each of the trenches increases along a direction toward the substrate;
removing the mask layer;
connecting the light emitting semiconductor devices to a conductive substrate, wherein the light emitting semiconductor devices are located between the conductive substrate and the substrate;
removing the substrate; and
forming an electrode on a first surface of each of the light emitting semiconductor devices, wherein the first surface faces against the conductive substrate.

22. The manufacturing method as claimed in claim 21, further comprising:
cutting the conductive substrate along the trenches to form a plurality of the light emitting diode chips separated from one another.

23. The manufacturing method as claimed in claim 21, further comprising:
forming a passivation layer on a sidewall of each of the light emitting semiconductor devices after the portion of the light emitting semiconductor devices exposed by the trenches is etched with use of the mask layer.

24. The manufacturing method as claimed in claim 21, further comprising:
forming a conductive bonding layer on the conductive substrate or on a second surface of each of the light emitting semiconductor devices before the light emitting semiconductor devices are connected to the conductive substrate, such that each of the light emitting semiconductor devices is connected to the conductive substrate through the conductive bonding layer, the second surface facing against the substrate.

25. The manufacturing method as claimed in claim 21, wherein a method of forming the trenches comprises mechanical cutting or laser cutting.

26. The manufacturing method as claimed in claim 21, wherein a method of etching the portion of the light emitting semiconductor devices exposed by the trenches comprises dry etching or wet etching.

27. The manufacturing method as claimed in claim 21, each of the light emitting semiconductor devices having a first surface and a second surface opposite to the first surface after the portion of the light emitting semiconductor devices exposed by the trenches is etched, each of the first surfaces connecting the substrate, a transverse sectional area of each of the light emitting semiconductor devices increasing from the first surface to the second surface.

28. The manufacturing method as claimed in claim 21, wherein a material of the mask layer comprises silicon dioxide.
